(19) United States
(12) Patent Application Publication
(10) Pub. No.: US 2026/0318968 A1
(43) Pub. Date: Oct. 15, 2026

(54) PROPAGATION ENVIRONMENT REPRODUCTION DEVICE, PROPAGATION ENVIRONMENT REPRODUCTION METHOD, AND PROPAGATION ENVIRONMENT REPRODUCTION SYSTEM

(71) Applicant: NTT, Inc., Tokyo (JP)

(72) Inventors: Ryotaro TANIGUCHI, Musashino-shi, Tokyo (JP); Tomoki MURAKAMI, Musashino-shi, Tokyo (JP); Tomoaki OGAWA, Musashino-shi, Tokyo (JP); Yasushi TAKATORI, Musashino-shi, Tokyo (JP)

(73) Assignee: NTT, Inc., Tokyo (JP)

(21) Appl. No.: 19/117,083

(22) PCT Filed: Oct. 4, 2022
(86) PCT No.: PCT/JP2022/037145

§ 371 Date: Mar. 31, 2025

(51) Int. Cl. G01R 29/10; H01Q 15/00

(52) U.S. Cl. CPC G01R 29/105; H01Q 15/0086

(57) ABSTRACT

The present disclosure relates to a propagation environment reproduction device that reproduces a propagation environment for verifying communication performance and the like of a measurement object. There is provided a propagation environment reproduction device including: an anechoic chamber that blocks an electromagnetic wave from the outside; a reconfigurable intelligent surface (RIS) that is installed in the anechoic chamber; a RIS control device that provides a control signal to the RIS; a transmission antenna that is installed in the anechoic chamber; a channel emulator that controls a characteristic of an electromagnetic wave transmitted from the transmission antenna; and a control server that controls the RIS control device and the channel emulator. The RIS is a reflector having a characteristic of changing a reflection pattern according to the control signal.

### TECHNICAL FIELD

The present disclosure relates to a propagation environment reproduction device, a propagation environment reproduction method, and a propagation environment reproduction system, and particularly relates to a propagation environment reproduction device, a propagation environment reproduction method, and a propagation environment reproduction system suitable for reproducing a propagation environment for verifying communication performance and the like of a measurement object.

### BACKGROUND ART

Non Patent Literature 1 described below discloses a technology related to an over the air (OTA) test for verifying the performance and quality of a device that is used for wireless communication as a measurement object. In the OTA test, one or a plurality of transmission antennas are disposed in an anechoic chamber or a shielded room, and an environment exhibiting the same propagation characteristics as the propagation characteristics of a real space is reproduced in the space.

In a case where a communication quality and the like of a measurement object are measured in a propagation environment in which the propagation characteristic occurring in a real space is reproduced, the communication quality and the like exhibited in the real space can be measured. Therefore, in a case where the OTA method is used, it is possible to easily and accurately evaluate the performance and the like of a device used for wireless communication.

### CITATION LIST

### Non Patent Literature

Non Patent Literature 1:“MIMO OTA Test for a Mobile Station Performance Evaluation”, Ya Jing, Hongwei Kong, and Moray Rumney, IEEE Instrumentation & Measurement Magazine, p43-p50, June 2016

### SUMMARY OF INVENTION

### Technical Problem

Incidentally, the largest problem with implementation of the OTA test is how to accurately reproduce a desired wireless propagation environment occurring in a real space. Meanwhile, as a device that controls reflection of radio waves, a reflector called a reconfigurable intelligent surface (RIS) is known.

The RIS is a reflector which uses a metamaterial technology and of which the characteristic is variable. Metamaterial means to artificially change a characteristic of a substance. According to a metamaterial technology, for example, a phenomenon in which a refractive index of an electromagnetic wave becomes a negative value may also occur.

The present disclosure has been made in view of the above problems, and a first object of the present disclosure is to provide a propagation environment reproduction device that accurately reproduces a desired wireless propagation environment by disposing a RIS in a space such as an anechoic chamber and simultaneously controlling a reflection direction and a reflection intensity of an electromagnetic wave by the RIS.

Further, a second object of the present disclosure is to provide a propagation environment reproduction method for accurately reproducing a desired wireless propagation environment by disposing a RIS in a space such as an anechoic chamber and simultaneously controlling a reflection direction and a reflection intensity of an electromagnetic wave by the RIS.

Further, a third object of the present disclosure is to provide a propagation environment reproduction system that accurately reproduces a desired wireless propagation environment by disposing a RIS in a space such as an anechoic chamber and simultaneously controlling a reflection direction and a reflection intensity of an electromagnetic wave by the RIS.

### Solution to Problem

In order to achieve the above object, according to a first aspect, preferably, there is provided a propagation environment reproduction device including: a reconfigurable intelligent surface (RIS) that is installed in a propagation environment reproduction space for reproducing a propagation environment of an electromagnetic wave; a RIS control device that provides a control signal to the RIS; a transmission antenna that is installed in the propagation environment reproduction space; a channel emulator that controls a characteristic of an electromagnetic wave transmitted from the transmission antenna; and a control server that controls the RIS control device and the channel emulator, in which the RIS is a reflector having a characteristic of changing a reflection pattern according to the control signal.

Further, according to a second aspect, preferably, there is provided a propagation environment reproduction method for reproducing a desired propagation environment using a RIS that is installed in a propagation environment reproduction space for reproducing a propagation environment of an electromagnetic wave and a transmission antenna that is installed in the propagation environment reproduction space, the RIS being a reflector having a characteristic of changing a reflection pattern according to a control signal, the propagation environment reproduction method including: calculating, while changing parameters related to the propagation environment reproduction space, the RIS, and the transmission antenna, a propagation characteristic occurring in the propagation environment reproduction space under each of said parameters by a simulation; creating a learning model that derives, when a propagation characteristic to be reproduced is provided, a parameter causing said propagation characteristic in the propagation environment reproduction space, the learning model being obtained by providing to a propagation environment model as training data a combination of an actual characteristic that is a propagation characteristic actually measured at a measurement position in a real space and a reproduction parameter that is a parameter calculated to cause a propagation characteristic which is same as the actual characteristic in the propagation environment reproduction space; causing the learning model to derive a parameter for causing a desired propagation characteristic by providing the desired propagation characteristic to the learning model; configuring the propagation environment reproduction space according to a specification indicated by the parameters derived by the learning model; disposing the RIS and the transmission antenna in the propagation environment reproduction space according to the specification indicated by the parameter derived by the learning model; controlling the RIS such that the RIS forms a reflection pattern indicated by the parameter derived by the learning model; and controlling a transmission signal from the transmission antenna such that the transmission antenna transmits an electromagnetic wave with a characteristic indicated by the parameters derived by the learning model.

Further, according to a third aspect, preferably, there is provided a propagation environment reproduction system including: a RIS that is installed in a propagation environment reproduction space for reproducing a propagation environment of an electromagnetic wave; and a transmission antenna that is installed in the propagation environment reproduction space, in which the RIS is a reflector having a characteristic of changing a reflection pattern according to a control signal, the propagation environment reproduction space is configured according to a specification indicated by a parameter which is set to reproduce a desired characteristic which is a propagation characteristic occurring at a measurement position in a real space, the RIS and the transmission antenna are disposed according to the specification indicated by the parameters, and the propagation environment reproduction system is configured to execute: a function of controlling the RIS such that the RIS forms a reflection pattern indicated by the parameter; and a function of controlling a transmission signal from the transmission antenna such that the transmission antenna transmits an electromagnetic wave with a characteristic indicated by the parameter.

### Advantageous Effects of Invention

According to the first aspect to the third aspect, by simultaneously controlling the reflection direction and the reflection intensity of the electromagnetic wave by the RIS, a desired wireless propagation environment can be accurately reproduced.

### BRIEF DESCRIPTION OF DRAWINGS

FIG. 1 is a diagram illustrating an overall configuration of a propagation environment reproduction device according to a first embodiment of the present disclosure;

FIG. 2 is a flowchart for explaining a procedure of deriving a parameter for reproducing a desired propagation environment in the propagation environment reproduction device illustrated in FIG. 1;

FIG. 3A is a diagram for explaining one of typical characteristics that can be provided to a RIS;

FIG. 3B is a diagram for explaining other typical characteristics that can be provided to the RIS;

FIG. 4A is a diagram illustrating a state of reflection occurring in a normal room;

FIG. 4B is a diagram for explaining a limit of the RIS that controls reflection power;

FIG. 5 is a diagram for explaining characteristics of reflection by the RIS that controls a reflection direction;

FIG. 6A is a diagram illustrating a state where the device according to the first embodiment of the present disclosure simultaneously controls reflection power and a reflection direction by using the RIS that controls the reflection direction;

FIG. 6B is a diagram illustrating a state where the device according to the first embodiment of the present disclosure causes unnecessary reflected signals from the RIS to be absorbed and eliminated by an absorber;

FIG. 7 is a diagram for explaining a hardware configuration of a control server included in the device according to the first embodiment of the present disclosure; and

FIG. 8 is a flowchart for explaining a flow when evaluating communication performance or the like of a measurement object using the device according to the embodiment of the present disclosure.

### DESCRIPTION OF EMBODIMENTS

### First Embodiment

### [Configuration of First Embodiment]

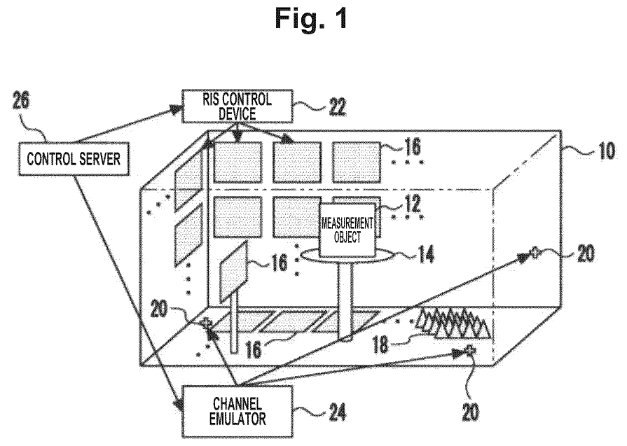

FIG. 1 is a diagram illustrating an overall configuration of a propagation environment reproduction device according to a first embodiment of the present disclosure. The propagation environment reproduction device according to the present embodiment includes an anechoic chamber 10. The anechoic chamber 10 is a chamber capable of blocking an influence of an electromagnetic wave from the outside, and may be referred to as a shielded room or an echo chamber. In the present embodiment, the anechoic chamber 10 is used for the purpose of reproducing a desired propagation environment for a wireless signal, more specifically, an actual propagation environment occurring in a real space such as a city street, in the anechoic chamber 10.

A measurement object 12 is disposed in the anechoic chamber 10. The measurement object 12 is configured with, for example, a mobile terminal or the like including a plurality of antennas for realizing a MIMO function. In the example illustrated in FIG. 1, the measurement object 12 is placed on a stand 14. The stand 14 is used to hold the measurement object 12 in a desired space in the anechoic chamber 10. In a real space such as a city street, a situation may occur in which a mobile terminal or the like is mounted on a drone and is located in the air. In a case where the stand 14 is used, the measurement object 12 can be held at a position in the anechoic chamber 10 corresponding to the air in the real space.

A plurality of RISs 16 are disposed inside the anechoic chamber 10. The RIS 16 can be installed on a wall surface, a ceiling, or a floor surface of the anechoic chamber 10. Further, the RIS 16 can also be disposed in the air in the anechoic chamber 10 by being supported by a jig installed on a floor surface or by being suspended from a ceiling (not illustrated).

In the anechoic chamber 10, a radio wave absorber 18 can be disposed at an arbitrary place. The radio wave absorber 18 has a function of absorbing emitted electromagnetic waves. According to the radio wave absorber 18, radio waves unnecessary for simulating a propagation environment in a real space can be eliminated inside the anechoic chamber 10.

One or more transmission antennas 20 are disposed in the anechoic chamber 10. The position of the transmission antenna 20 can be arbitrarily determined. FIG. 1 illustrates an example in which three transmission antennas 20 are disposed inside the anechoic chamber 10.

A RIS control device 22 is connected to the RISs 16. In the present embodiment, all the RISs 16 have a function of making a reflection direction of the electromagnetic waves, more specifically, a reflection pattern of the electromagnetic waves variable. The RIS control device 22 provides a control signal to each of the RISs 16. Each of the RISs 16 changes the reflection pattern according to the received control signal. Therefore, in the present embodiment, a desired reflection pattern can be formed by each of the RISs 16 installed in the anechoic chamber 10.

A channel emulator 24 is connected to the transmission antennas 20. The channel emulator has a function of controlling characteristics of the electromagnetic waves transmitted from the transmission antennas 20. Specifically, the channel emulator 24 can control a radiation direction, power, a radiation timing, and the like of the electromagnetic waves transmitted from the transmission antennas 20.

A control server 26 is connected to the RIS control device 22 and the channel emulator 24. The control server 26 controls the RIS control device 22 and the channel emulator 24 such that a desired propagation environment is reproduced at a position of a reception antenna included in the measurement object 12. In a case where specifications of the propagation environment reproduction device are appropriately set and then the RIS control device 22 and the channel emulator 24 are appropriately controlled, a desired propagation environment can be reproduced inside the anechoic chamber 10, particularly, at a position of the measurement object 12.

The configuration illustrated in FIG. 1 is an example of one form of the propagation environment reproduction device. A shape and a size of the anechoic chamber 10 can be changed. The shape can be, for example, a sphere, an n-hedron (n is an integer), an n-prism, an n-pyramid, or the like. The RIS 16 and the transmission antenna 20 can be disposed in any number equal to or larger than 1, and can be disposed at any position.

[Method for deriving Reproduction Parameter]

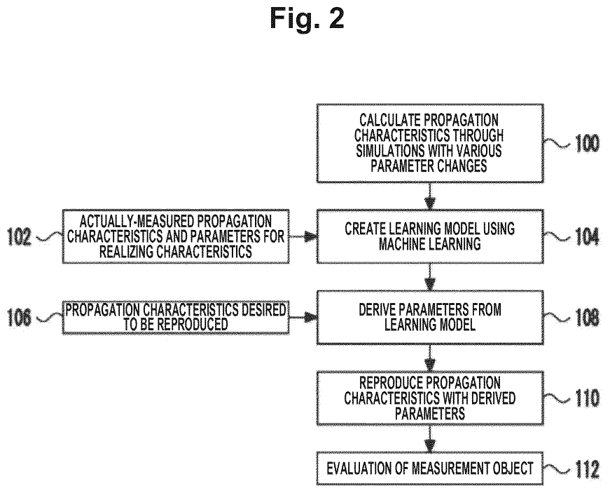

FIG. 2 is a flowchart for explaining a procedure of deriving a parameter for reproducing a desired propagation environment in the propagation environment reproduction device illustrated in FIG. 1.

Here, first, various parameters related to the characteristics of the propagation environment reproduction device are variously changed, and the propagation characteristics occurring in the anechoic chamber 10 under a combination of the respective parameters are calculated by a simulation (step 100). A type of the simulation may be, for example, ray tracing (a ray launching method), ray tracing (an imaging method), electromagnetic field analysis (FDTD method), or the like.

As parameters to be set, for example, the following parameters are used.
A shape, a size, and a material of the anechoic chamber 10
A shape, a size, the number, disposition, a controllable angle, a controllable reflectance of the RIS 16
A location and the number of the transmission antenna 20, and characteristics of transmission signals
A location and the number of the reception antenna, and characteristics of reception signals
A direction of transmission beams
A position, a size, the number, and a shape of the radio wave absorber

The propagation characteristic is a characteristic of the electromagnetic wave at a reception point, and specifically, the following physical quantity corresponds to the propagation characteristic.
Received power
Cross polarization ratio (XPR, vertical-horizontal power ratio)
Delay time
Arrival direction (horizontal/vertical)
Delay spread
Angle spread
Number of clusters included in a radio wave cluster

After the processing in step 100 is completed, next, a propagation characteristic (hereinafter, “actual characteristic”) actually occurring in a real space is specified. In addition, a parameter (hereinafter, “reproduction parameter”) that causes the actual characteristic in the anechoic chamber 10 is specified based on a result of the above simulation. By repeating this processing, a plurality of sets of actual characteristics and parameters are prepared (step 102).

The “actual characteristic” is a propagation characteristic that is actually measured at a position of the measurement object 12 in a state where a device as the measurement object 12 is actually disposed in a real space such as a city street. The “reproduction parameter” is a parameter that causes the “actual characteristic” in the anechoic chamber 10 and is obtained by a simulation. Therefore, in a case where the propagation environment reproduction device is prepared according to the reproduction parameters, the same characteristics as the “actual characteristics” occur inside the propagation environment reproduction device.

The set of “actual characteristics” and “reproduction parameters” is used as training data for machine learning. That is, in the present embodiment, the plurality of data sets prepared in step 102 are provided to a propagation environment model as training data for machine learning. Then, when an actual characteristic is given by repeating learning using a large number of training data, a learning model for deriving a parameter that causes the characteristic in the anechoic chamber 10 is created (step 104).

In a stage where the learning model has been created, a propagation characteristic (hereinafter, “desired characteristic”) to be reproduced in the anechoic chamber 10 is provided to the learning model (step 106).

Thereby, a parameter for causing the desired characteristic in the anechoic chamber 10 is derived from the learning model (step 108).

Thereafter, a propagation environment reproduction device is prepared according to the parameters derived in step 108, and electromagnetic waves are transmitted into the propagation environment reproduction device. Thereby, the desired characteristic is reproduced at the position of the measurement object 12 in the anechoic chamber 10 (step 110).

After the desired characteristics has been reproduced, communication performance, a communication quality, and the like of the measurement object 12 disposed in the anechoic chamber 10 are measured, and the measurement result is evaluated (step 112).

As described above, according to the propagation environment reproduction device of the present embodiment, the measurement object 12 can be evaluated in a state where the desired characteristics has been reproduced in the anechoic chamber 10. Therefore, according to the device, it is possible to accurately evaluate the capability of the measurement object 12 in a real space without performing measurement in a real space.

### [Characteristics of RIS]

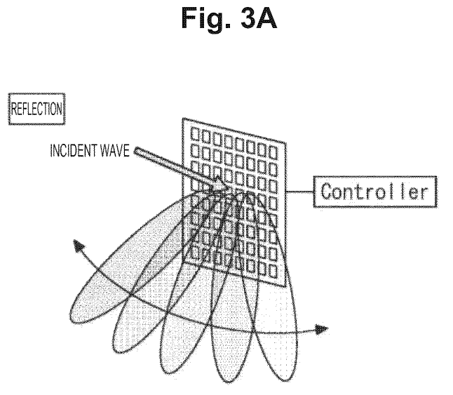

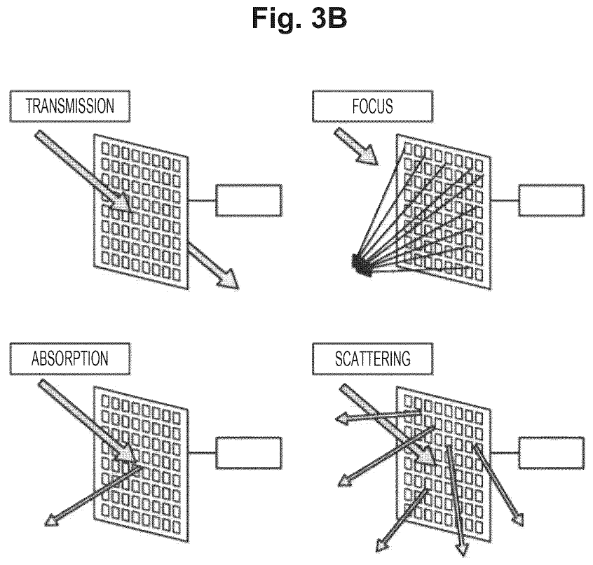

FIG. 3A is a diagram for explaining an example of characteristics that can be provided to the RIS using a metamaterial technology. As illustrated in FIG. 3A, the RIS can be provided with a characteristic of making a direction in which an incident wave is reflected variable according to a control signal provided from the controller.

FIG. 3B illustrates other typical characteristics that can be provided to the RIS. As illustrated in FIG. 3B, the RIS can be provided with a characteristic of transmitting the incident wave, a characteristic of focusing the reflected wave at a specific location, a characteristic of absorbing a part of the incident wave to reduce the intensity and reflecting the incident wave, a characteristic of scattering the incident wave, and the like. In addition to the characteristics illustrated in FIG. 3A, it is also possible to selectively provide the characteristics illustrated in FIG. 3B to the RIS according to the adopted structure.

The RIS 16 used in the present embodiment is provided with the characteristic illustrated in FIG. 3A, that is, the characteristic of making the direction of the reflected wave variable. More specifically, the RIS 16 according to the present embodiment is provided with a characteristic of making the reflection pattern variable according to the control signal.

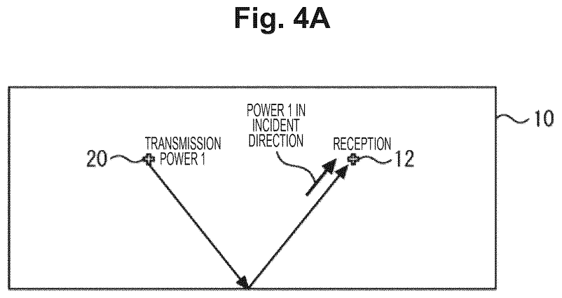

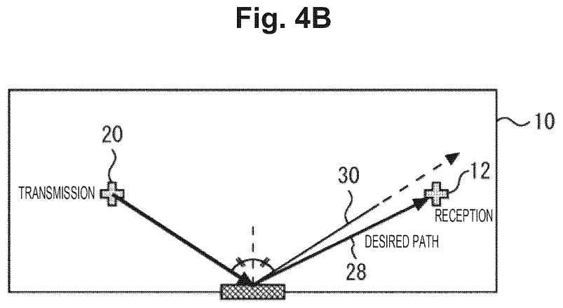

FIG. 4A illustrates a state of reflection occurring in a normal room. In this case, the electromagnetic wave emitted from the transmission antenna 20 is reflected by the wall surface, and thus the traveling direction of the electromagnetic wave is changed. The incident angle of the electromagnetic wave on the wall surface and the reflection angle of the electromagnetic wave on the wall surface are the same. Further, power 1 after reflection is maintained to be substantially equal to transmission power 1.

FIG. 4B illustrates a state of reflection in a case where the RIS having a characteristic that the reflection power is variable is disposed on the wall surface of the anechoic chamber 10. A path 28 illustrated in FIG. 4B indicates a desired path for causing the electromagnetic wave to enter the reception point where the measurement object 12 is placed. On the other hand, a path 30 indicates a path that actually occurs in this example. The RIS illustrated in FIG. 4B reflects the electromagnetic wave at a reflection angle similar to the reflection angle in the case illustrated in FIG. 4A. For this reason, in a case where the position of the transmission antenna 20 and the position of the measurement object 12 are not disposed on a target with the RIS interposed therebetween, the reflected electromagnetic wave does not reach the measurement object 12. As described above, by the RIS in which the reflection power is variable, although the power after reflection can be controlled, a situation where the reflected wave generated as a result cannot reach the measurement object 12 may occur. That is, in the RIS having such characteristics, it is impossible to cause the reflected wave having desired power to travel in a desired direction.

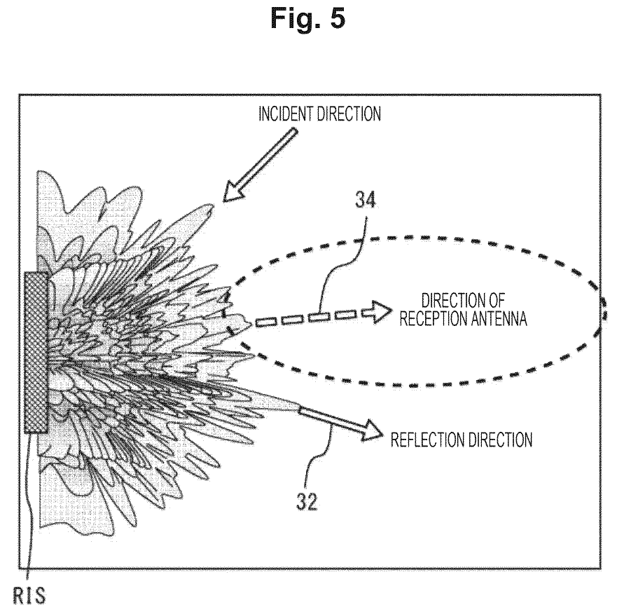

FIG. 5 is a diagram for explaining reflection characteristics of the RIS 16 used in the present embodiment in detail. As described above, the RIS 16 has a characteristic that the reflection direction is variable according to the control signal. FIG. 5 illustrates an example of a reflection pattern formed by providing a specific control signal to the RIS 16. Here, the largest reflection occurs in the reflection direction of the path 32. In addition, attenuated reflection occurs in the direction of the path 34. The reflection pattern of the RIS 16 changes according to the control signal. Therefore, in a state where the reception antenna is present in the direction of the path 34, in a case where a reflection pattern in which the reflection in the direction of the path 34 has desired power is generated, both a direction and an intensity of the reflection can be controlled by the RIS 16.

### [Control Example of Reflection Direction and Reflection Intensity]

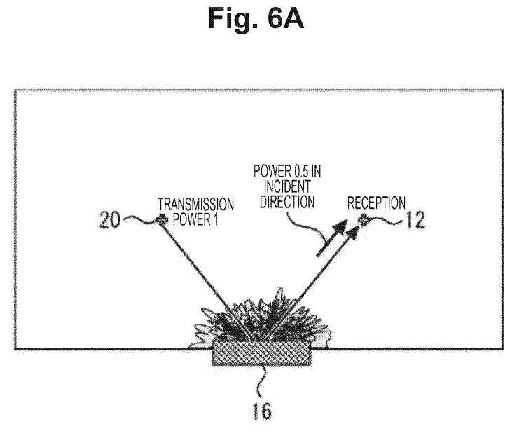

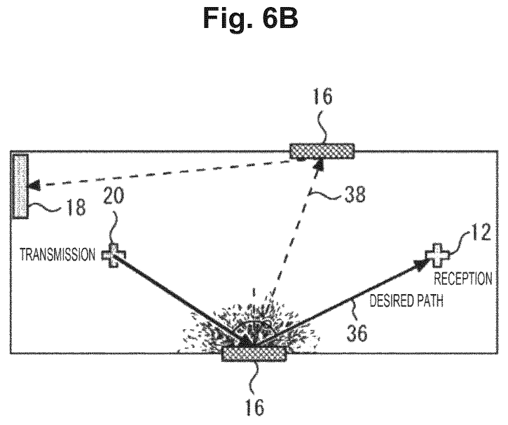

FIG. 6A illustrates an example of a state where the RIS 16 simultaneously controls the reflection direction and the reflection power of the electromagnetic wave transmitted from the transmission antenna 20. Here, the electromagnetic wave having power 1 is transmitted from the transmission antenna toward the RIS 16, and the RIS 16 reflects the electromagnetic wave having power 0.5 in the incident direction toward the measurement object 12. As described above, in a case where the reflection pattern illustrated in FIG. 6A is generated in the RIS 16, the reflected wave having the power reduced by half can be entered toward the measurement object 12. In this case, it is assumed that the reflected waves traveling in directions other than the direction toward the measurement object 12 are dispersed to an extent that the reflected waves do not affect the propagation environment of the reception point.

FIG. 6B illustrates an example in which the radio wave absorber 18 is used to absorb unnecessary reflected waves to create a desired propagation environment. The RIS 16 illustrated in FIG. 6B generates a high-intensity reflected wave in the direction of the path 38 when generating a reflected wave having a desired intensity toward the measurement object 12. Here, the reflected wave of the path 38 is reflected by the RIS 16 to be directed to the radio wave absorber 18. The radio wave absorber 18 has a function of absorbing electromagnetic waves. Therefore, the reflected wave having a high intensity toward the path 38 does not affect the propagation environment at the position where the measurement object 12 is placed. As a result, a desired propagation space is reproduced inside the anechoic chamber 10 regardless of the generation of the reflected wave in the direction of the path 38.

### [Hardware Configuration of Control Server]

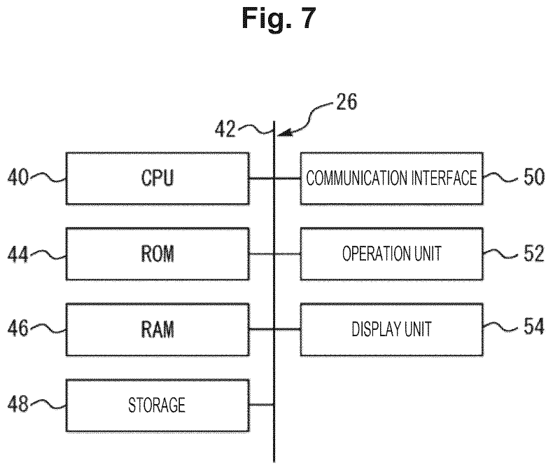

FIG. 7 illustrates a hardware configuration of the control server 26. The control server 26 is configured with a general computer system, and includes a central processing unit (CPU) 40. Memories such as a ROM 44, a RAM 46, and a storage 48 are connected to the CPU 40 via a communication bus 42. The communication bus 42 is further connected to a communication interface 50, and an operation unit 52 and a display unit 54 serving as user interfaces.

In a case where the CPU 40 executes a program stored in the ROM 44, the control server 26 implements the above-described various functions. Specifically, in a case where the CPU 40 executes the processing according to the program, the control server 26 implements the simulation in step 100, the learning in step 104, the parameter derivation in step 108, the control of the RIS 16 and the channel emulator 24 in step 110, and the evaluation of the measurement object 12 in step 112.

### [Evaluation of Measurement Object]

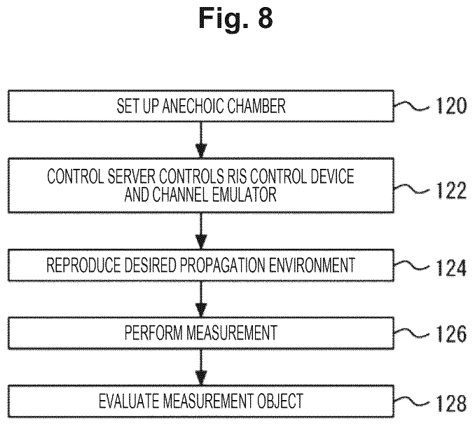

FIG. 8 is a flowchart for explaining in detail the processing of step 110 and step 112 illustrated in FIG. 2. Here, first, the anechoic chamber 10 is set up (step 120). Specifically, the anechoic chamber 10 is set up with the shape, the size, and the material indicated by the parameters derived in step 108. In addition, the RIS 16, the transmission antenna 20, and the reception antenna (measurement object 12) are installed in the anechoic chamber 10 according to the parameters. In a case where the parameter requires installation of the radio wave absorber 18, the radio wave absorber is also installed.

Next, the control server 26 controls the RIS control device 22 and the channel emulator 24 as indicated by the parameters (step 122).

Thereby, a desired propagation environment simulating the characteristics of a real space is reproduced inside the anechoic chamber 10, particularly, at the position of the measurement object 12 (step 124). In this step, it may be verified that a desired propagation environment is reproduced using a reception antenna of which the performance is known.

After the desired propagation space is reproduced in the anechoic chamber 10, the control server 26 measures a communication quality and the like of the measurement object 12 (step 126).

Next, the control server 26 is caused to execute evaluation of the measurement object 12 based on the measurement result (step 128).

### [Modification Example of the First Embodiment]

In the above example, the control server 26 is caused to perform the simulation in step 100, the learning in step 104, and the parameter derivation in step 108. On the other hand, the present disclosure is not limited thereto. These pieces of processing may be executed by another computer prepared separately from the control server 26.

Further, in the above example, the control server 26 is caused to perform the measurement of the communication quality and the like of the measurement object 12 and the evaluation of the measurement object 12 based on the measurement result. On the other hand, the present disclosure is not limited thereto. These pieces of processing may be executed by another evaluation device prepared separately from the control server 26.

Further, in the first embodiment described above, the propagation environment in a real space is reproduced in the anechoic chamber 10. On the other hand, the present disclosure is not limited thereto. The space for reproducing the propagation environment may be an outdoor space, or may be a normal indoor space that does not have a shielding function.

### REFERENCE SIGNS LIST

10 Anechoic chamber
12 Measurement object
16 RIS
18 Radio wave absorber
20 Transmission antenna
22 RIS control device
24 Channel emulator
26 Control server
40 CPU
44 ROM

1. A propagation environment reproduction device comprising:
a reconfigurable intelligent surface (RIS) that is installed in a propagation environment reproduction space for reproducing a propagation environment of an electromagnetic wave;
a RIS controller that provides a control signal to the RIS;
a transmission antenna that is installed in the propagation environment reproduction space;
a channel emulator that controls a characteristic of an electromagnetic wave transmitted from the transmission antenna; and
a control server that controls the RIS controller and the channel emulator,
wherein the RIS is a reflector having a characteristic of changing a reflection pattern according to the control signal.

2. The propagation environment reproduction device according to claim 1, wherein
the propagation environment reproduction space is configured according to a specification indicated by a parameter which is set to reproduce a desired characteristic which is a propagation characteristic occurring at a measurement position in a real space,
the RIS and the transmission antenna are disposed according to the specification indicated by the parameters, and
the control server is configured to execute:
controlling the RIS controller such that the RIS forms a reflection pattern indicated by the parameter; and
controlling the channel emulator such that the transmission antenna transmits the electromagnetic wave with a characteristic indicated by the parameter.

3. The propagation environment reproduction device according to claim 2, wherein the reflection pattern is a pattern that causes reflection with a desired intensity in a direction toward a measurement position in the propagation environment reproduction space.

4. The propagation environment reproduction device according to claim 2, further comprising
a radio wave absorber that is installed in the propagation environment reproduction space so as to absorb an electromagnetic wave reflected by the RIS in a direction different from a direction toward the measurement position under the reflection pattern.

5. A propagation environment reproduction method for reproducing a desired propagation environment using a RIS that is installed in a propagation environment reproduction space for reproducing a propagation environment of an electromagnetic wave and a transmission antenna that is installed in the propagation environment reproduction space, the RIS being a reflector having a characteristic of changing a reflection pattern according to a control signal, the propagation environment reproduction method including:
calculating, while changing parameters related to the propagation environment reproduction space, the RIS, and the transmission antenna, a propagation characteristic occurring in the propagation environment reproduction space under each of said parameters by a simulation;
creating a learning model that derives, when a propagation characteristic to be reproduced is provided, a parameter causing said propagation characteristic in the propagation environment reproduction space, the learning model being obtained by providing to a propagation environment model as training data a combination of an actual characteristic that is a propagation characteristic actually measured at a measurement position in a real space and a reproduction parameter that is a parameter calculated to cause a propagation characteristic which is same as the actual characteristic in the propagation environment reproduction space;
causing the learning model to derive a parameter for causing a desired propagation characteristic by providing the desired propagation characteristic to the learning model;
configuring the propagation environment reproduction space according to a specification indicated by the parameter derived by the learning model;
disposing the RIS and the transmission antenna in the propagation environment reproduction space according to the specification indicated by the parameter derived by the learning model;
controlling the RIS such that the RIS forms a reflection pattern indicated by the parameter derived by the learning model; and
controlling a transmission signal from the transmission antenna such that the transmission antenna transmits an electromagnetic wave with a characteristic indicated by the parameter derived by the learning model.

6. The propagation environment reproduction method according to claim 5, wherein the reflection pattern is a pattern that causes reflection with a desired intensity in a direction toward a measurement position in the propagation environment reproduction space.

7. The propagation environment reproduction method according to claim 6, further including
installing, in the propagation environment reproduction space, a radio wave absorber that absorbs an electromagnetic wave reflected by the RIS in a direction different from a direction toward the measurement position under the reflection pattern.

8. A propagation environment reproduction system comprising:
a RIS that is installed in a propagation environment reproduction space for reproducing a propagation environment of an electromagnetic wave; and
a transmission antenna that is installed in the propagation environment reproduction space,
wherein the RIS is a reflector having a characteristic of changing a reflection pattern according to a control signal,
the propagation environment reproduction space is configured according to a specification indicated by a parameter which is set to reproduce a desired characteristic which is a propagation characteristic occurring at a measurement position in a real space,
the RIS and the transmission antenna are disposed according to the specification indicated by the parameter, and
the propagation environment reproduction system is configured to execute:
a function of controlling the RIS such that the RIS forms a reflection pattern indicated by the parameter; and
a function of controlling a transmission signal from the transmission antenna such that the transmission antenna transmits an electromagnetic wave with a characteristic indicated by the parameter.
